(19) United States
(12) Patent Application Publication
(10) Pub. No.: US 2026/0371786 A1
(43) Pub. Date: Nov. 19, 2026

(54) SINGLE PHOTON AVALANCHE DIODE

(71) Applicant: STMicroelectronics International N.V., Geneva (CH)

(72) Inventors: Bastien MAMDY, Le Versoud (FR); Isobel NICHOLSON, Edinburgh (GB)

(73) Assignee: STMicroelectronics International N.V., Geneva (CH)

(21) Appl. No.: 19/676,200

(22) Filed: May 13, 2026

(30) Foreign Application Priority Data
May 16, 2025 (FR) FR2505246

(51) Int. Cl. H10F 77/00; H10F 30/225

(52) U.S. Cl. CPC H10F 77/959; H10F 30/225

(57) ABSTRACT

A single photon avalanche diode includes a first semiconductor region doped of a first conductivity type, and a second semiconductor region doped of a second conductivity type opposite to the first conductivity type. The first and second regions constitute a PN junction. A third semiconductor region doped of the second conductivity type is separated from the first and second semiconductor regions. During operation of the single photon avalanche diode, a first voltage is applied to the third region, the value of the first voltage being such that a value of a depletion voltage of the single photon avalanche diode is decreased.

### PRIORITY CLAIM

This application claims the priority benefit of French Application for Patent No. FR2505246, filed on May 16, 2025, the content of which is hereby incorporated by reference in its entirety to the maximum extent allowable by law.

### TECHNICAL FIELD

The present disclosure relates generally to optoelectronic devices and, more particularly, to devices comprising a single photon avalanche diode (SPAD).

### BACKGROUND

A single-photon avalanche diode (SPAD) is a solid-state photodetector within the same family as photodiodes and avalanche photodiodes (APDs), while also being fundamentally linked with basic diode behaviors. As with photodiodes and APDs, a SPAD is based around a semiconductor PN junction that can be illuminated with non-ionizing radiation. The fundamental difference between SPADs and APDs or photodiodes, is that a SPAD is biased well above its reverse-bias breakdown voltage and has a structure that allows operation without damage or undue noise.

The electric field of the SPAD is high enough that a single charge carrier injected into the depletion layer can trigger a self-sustaining avalanche. The current continues until the avalanche is quenched. To that end, the SPAD is associated with a quenching circuit.

### SUMMARY

One embodiment provides a control method for a device comprising a single photon avalanche diode, where the single photon avalanche diode comprises: a first semiconductor region doped of a first conductivity type; a second semiconductor region doped of a second conductivity type opposite to the first conductivity type, the first and second semiconductor regions constituting a PN junction; a third semiconductor region doped of the second conductivity type and separated from the first and second semiconductor regions. The method comprises applying a first voltage to the third semiconductor region, a value of the first voltage being, during operation of the single photon avalanche diode, such that a value of a depletion voltage of the single photon avalanche diode is decreased.

Another embodiment provides a device comprising a single photon avalanche diode, the single photon avalanche diode comprising: a first semiconductor region doped of a first conductivity type; a second semiconductor region doped of a second conductivity type opposite to the first conductivity type, the first and second semiconductor regions constituting a PN junction; a third semiconductor region doped of the second conductivity type and separated from the first and second semiconductor regions, the device being configured to apply a first voltage to the third semiconductor region, a value of the first voltage being configured so that a value of a depletion voltage of the single photon avalanche diode is decreased during operation of the single photon avalanche diode.

According to an embodiment, the single photon avalanche diode is delimited by an element.

According to an embodiment, the element is a trench comprising a conductive core and a dielectric sheath.

According to an embodiment, the third semiconductor region surrounds laterally the first and second semiconductor regions.

According to an embodiment, the third semiconductor region is separated from the first and second semiconductor regions by a dielectric trench.

According to an embodiment, the single photon avalanche diode comprises a fourth semiconductor region separated from the first semiconductor region by the second semiconductor region.

According to an embodiment, the single photon avalanche diode is formed in a substrate, the first and second semiconductor regions having surfaces coplanar with an upper face of the substrate, the fourth semiconductor region being surrounded by the second and third semiconductor regions and the trench.

According to an embodiment, the single photon avalanche diode is formed in a substrate, the first and second semiconductor regions having surfaces coplanar with an upper face of the substrate, the upper face of the fourth semiconductor region being covered by the second and third semiconductor regions and the trench, the lateral faces of the fourth semiconductor region being covered by the element and the lower face of the fourth semiconductor region being covered by a fifth semiconductor region doped of the second conductivity type.

According to an embodiment, third semiconductor region is separated from the first and second semiconductor regions by the fourth semiconductor region.

According to an embodiment, the single photon avalanche diode is formed in a substrate, the first and second semiconductor regions having surfaces coplanar with an upper face of the substrate, the third semiconductor region covering the lower face of the fourth semiconductor region.

According to an embodiment, the first voltage is configured to be variable.

According to an embodiment, the first voltage is configured to depend on the temperature.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example of a SPAD;

FIG. 2 illustrates the behavior of the SPAD of FIG. 1;

FIG. 3A and FIG. 3B illustrate an embodiment of a SPAD;

FIG. 4 illustrates the behavior of the SPAD of FIGS. 3A and 3B;

FIG. 5 illustrates another embodiment of a SPAD;

FIG. 6 illustrates another embodiment of a SPAD; and

FIG. 7 illustrates another embodiment of a SPAD.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10 % or 10°, and preferably within 5 % or 5°.

The device is for example intended for the automotive industry. The autonomous driving trend generates an increasing demand for 3D telemetry sensors. Such sensors are for example SPAD LIDARs that are able to generate 3D images and videos. Such sensors for example comprise direct “Time Of Flight” imaging technology combined to standard 2D intensity imaging technology. Indeed, SPAD matrix technology is able to produce both.

The device can for example be used in the industrial field. Object recognition and manipulation by industrial robots, generates an increasing demand for 3D telemetry sensors, such as SPAD LIDARs.

The device is for example intended for being used in personal electronics. Face recognition and sophisticated autofocus cameras in smart phones and other consumer electronic devices increasingly demand for 3D telemetry sensors, such as SPAD LIDARs

The device is, for example, intended for being used in communication equipment, or in computers and peripherals. For example, photonic detectors or optical communication devices integrates SPAD sensors for their high sensitivity, time correlated precision and the strong output signal due to avalanche carrier multiplication.

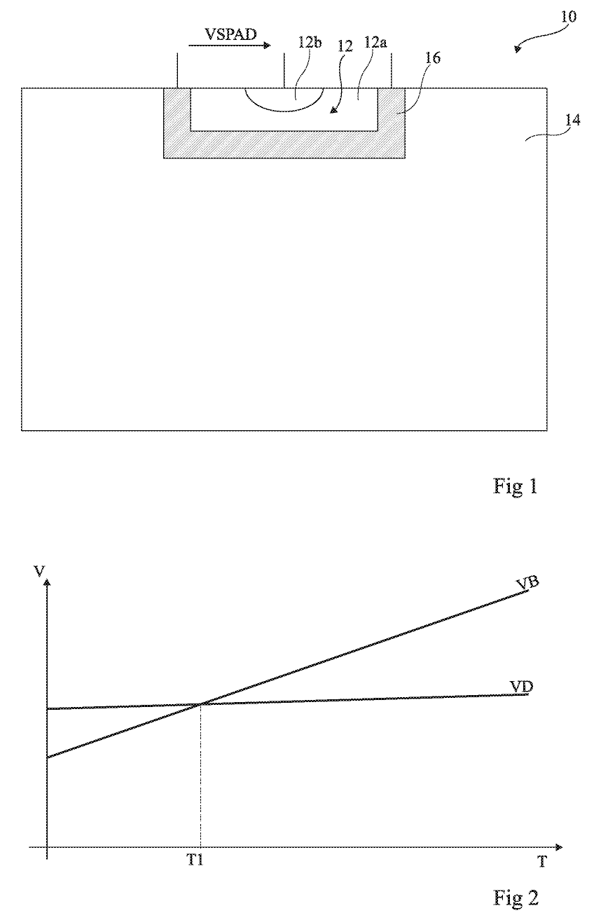

FIG. 1 illustrates an example of a single-photon avalanche diode (SPAD) 10.

The SPAD 10 comprises a semiconductor region 12 doped of a first type of conductivity. For example, the region 12 is n-doped. The region 12 is located in a semiconductor substrate 14. The region 12 has an upper surface coplanar with an upper face of the substrate.

Region 12 comprises parts 12a and 12b. Part 12b is more heavily doped of the first type than region 12a. For example, the concentration of dopants in region 12b is at least ten times higher than the concentration of dopants of part 12a. Part 12b has an upper surface coplanar with the upper face of the substrate 14 and coplanar with the upper face of the region 12. Part 12b is preferably located at the center of the upper face of the region 12. For example, part 12b does not extend over the entire height (thickness) of the region 12. In other words, the part 12b is, for example, separated from the lower face, in other words, the opposite face to the upper face, of the region 12 by a portion of part 12a.

The SPAD 10 comprises a semiconductor region 16 doped of a second type of conductivity, opposite to the first type. For example, the region 16 is p-doped. The region 16 is located in the semiconductor substrate 14. The region 16 surrounds and is in contact with the region 12. Furthermore, the region 16 comprises upper surface(s) coplanar with the upper face of the substrate.

Regions 12 and 16 are in contact with each other and form the PN junction of the SPAD 10. Region 12 constitutes the cathode of the SPAD and region 16 constitutes the anode of the SPAD.

When the SPAD is in operation, a voltage VSPAD is applied between the anode and the cathode of the SPAD in order to bias it well above its reverse-bias breakdown voltage.

FIG. 2 illustrates the behavior of the SPAD of FIG. 1. More precisely, FIG. 2 illustrates the value of two voltages (V), the depletion voltage VD of the SPAD 10 of FIG. 1 and the breakdown voltage VB of the SPAD 10 of FIG. 1, as functions of the temperature (T).

The depletion voltage of the SPAD 10 is the lowest value that needs to be taken by the voltage VSPAD so that the substrate 14 surrounding the region 16 is depleted. The breakdown voltage of the SPAD 10 is the lowest value that needs to be taken by the voltage VSPAD so that the injection of a carrier causes an avalanche.

FIG. 2 shows that, above a temperature T1, the value of the depletion voltage is lower than the value of the breakdown voltage. Therefore, the substrate is depleted before an avalanche can be caused. Below the temperature T1, the value of the depletion voltage is higher than the value of the breakdown voltage. Therefore, an avalanche can be triggered in the SPAD while the part of the substrate below the region 16 has not been fully depleted.

When the device operates at a temperature lower than T1, the risk of afterpulsing increases. Indeed, as the substrate 14, which operates as a stockage region, is not depleted, pockets of charges can form. Those charges can then trigger the SPAD at a later time.

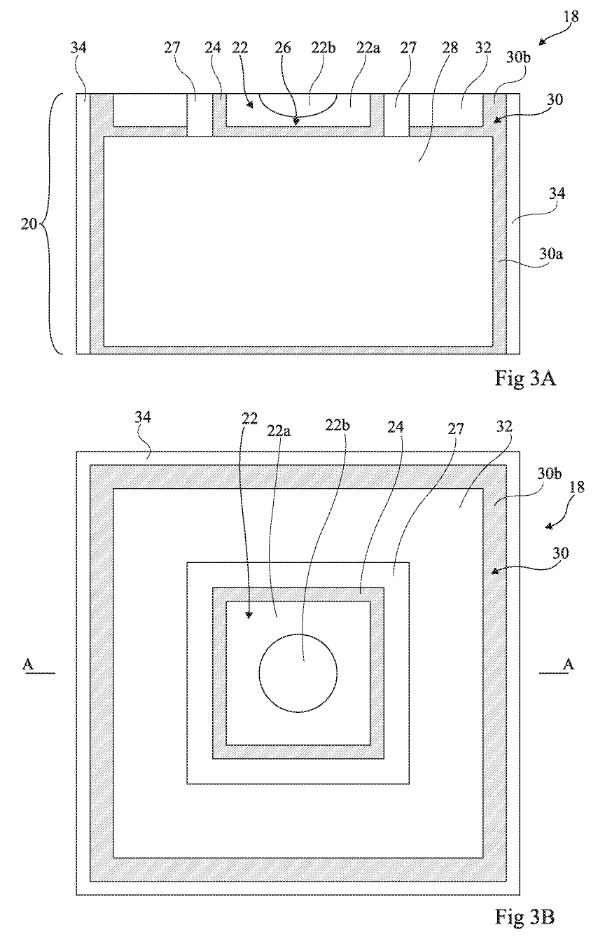

FIGS. 3A, and 3B illustrate an embodiment of a SPAD 18. More precisely, FIGS. 3A and 3B illustrates a part of a device, for example a chip, comprising the SPAD 18. FIG. 3A is a cut view according to a plan A-A of FIG. 3B. FIG. 3B is a top view of the device of FIG. 3A.

SPAD 18 is located in a substrate 20. The substrate 20 is, for example, a semiconductor substrate, for example a silicon substrate.

SPAD 18 comprises a region 22. Region 22 is made of a semiconductor material, for example made of silicon. Region 22 is, for example, a doped region of the substrate 20. Region 22 has an upper surface coplanar with an upper face of the substrate 20. Region 22 is, for example, an n-doped region. Region 22 constitutes then the cathode of the SPAD 18.

Region 22 comprises parts 22a and 22b. Part 22b is more heavily doped than region 22a. For example, the concentration of dopants in region 22b is at least ten times higher than the concentration of dopants of part 22a. Part 22b has an upper surface coplanar with the upper face of the substrate 20 and coplanar with the upper face of the region 22. Part 22b is preferably located at the center of the upper face of the region 22. Preferably, part 22b does not extend across the entire height (thickness) of the region 22. In other words, the part 22b is separated from the lower face, in other words, the opposite face to the upper face, of the region 22 by a portion of part 22a.

SPAD 18 comprises a region 24. Region 24 is made of a semiconductor material, for example made of silicon. Region 24 is, for example, a doped region of the substrate 20. Region 24 is doped of the opposite conductivity type from the conductivity type of region 22. Region 24 is, for example, a p-doped region. Region 24 constitutes then the anode of the SPAD 18. Region 24 preferably surrounds region 22. More precisely, region 24 covers and is in contact with the lower face of region 22. Preferably, region 24 covers and is in contact with the lateral faces of region 22. Preferably, region 24 reaches the upper face of the substrate 20. Preferably, region 24 reaches the plan of the upper face of region 22.

Part 22b of region 22 is separated from the lower face of the region 22, and therefore region 24, by a multiplication region 26.

SPAD 18 comprises a trench 27. Trench 27 is an insulation trench. In other words, trench 27 is made of an insulating material, for example made of a dielectric material, for example made of silicon oxide. Trench 27 surrounds laterally region 24. Trench 27 is, for example, in contact with region 24. Trench 27 extends, for example, from the upper face of the substrate, in other words the upper face of regions 22 and 24, to the lower face of region 24. Trench 27 preferably extends along the lateral faces of the region 24.

SPAD 18 comprises a region 28, constituting a space charge region. Region 28 is made of a semiconductor material, for example made of silicon. Region 28 is, for example, a doped region of the substrate 20. Region 28 is, for example, doped of the same type of conductivity as region 22. Region 28 is, for example, an n-doped region. Region 28 is preferably a buried region. Region 28 extends below the regions 22 and 24 and below the trench 27. In other words, the region 28 is located between region 24 and the lower face of the substrate. The region 24 is located between the region 22 and the region 28. The region 24 and the trench 27 cover part of the upper face of the region 28, preferably a central part.

SPAD 18 comprises a region 30. Region 30 is made of a semiconductor material, for example made of silicon. Region 30 is, for example, a doped region of the substrate 20. Region 30 is preferably of the same conductivity type as the region 24. Region 30 is, for example, a p-doped region.

Region 30 comprises parts 30a and 30b. Part 30a of region 30 surrounds at least partially the region 28. In the example of FIGS. 3A and 3B region 28 is entirely surrounded by region 30, more precisely by part 30a of region 30, by region 24 and by trench 27. For example, part 30a covers, and is preferably in contact with, the lower face of region 28, the lateral faces of region 28 and a portion of the upper face of region 28, more precisely the portion of the upper face of region 28 which is not covered by region 24 and trench 27. Therefore, part 30a is preferably in contact with trench 27 and is not in contact with regions 22 and 24. Region 24 and part 30a are separated by trench 27.

For example, part 30a has a lower surface that is coplanar with the lower face of the substrate 20. Therefore, region 30 extends, for example, through the entire chip.

Part 30b of the region 30 is located between part 30a and the upper face of the substrate. More precisely, part 30b extends from the upper face of part 30a to the level of the upper face of region 22. Parts 30a and 30b are in contact with each other. Part 30b surrounds laterally the regions 22 and 24 and the trench 27.

SPAD 18 comprises, for example, a region 32. Region 32 is made of a semiconductor material, for example made of silicon. Region 32 is, for example, a doped region of the substrate 20. Region 32 has an upper surface coplanar with an upper face of the substrate 20. Region 32 is, for example, a n-doped region. Region 32 separates part 30b of region 30 from the trench 27.

The device comprises an element 34 surrounding the SPAD. The element 34 preferably extends along the entire height of region 30. The element 34 is, for example, in contact with region 30. The element 34 is configured to demarcate the SPAD. The element 34 is, for example, an insulating wall made of a dielectric material, or an insulating trench comprising a conductive core and a dielectric sheath, or a semiconductor wall doped, for example, of the opposite conductivity type to the conductivity type of region 30.

Regions 22 and 24 are configured to receive, between them, the voltage VSPAD as described in relation with FIG. 1. In other words, region 22, and more specifically part 22b of region 22, is configured to receive a voltage, for example the voltage VSPAD, and region 24 is configured to receive a voltage, for example a reference voltage GND.

Furthermore, region 30 is configured to receive a voltage VPT, referred to as a punch through voltage, configured to optimize the depletion voltage. Voltage VPT is distinct from the voltages applied to regions 22 and 24. Voltage VPT has, for example, a positive value during the operation of the SPAD.

SPAD 18 is therefore configured to receive three distinct voltages, for example only three distinct voltages.

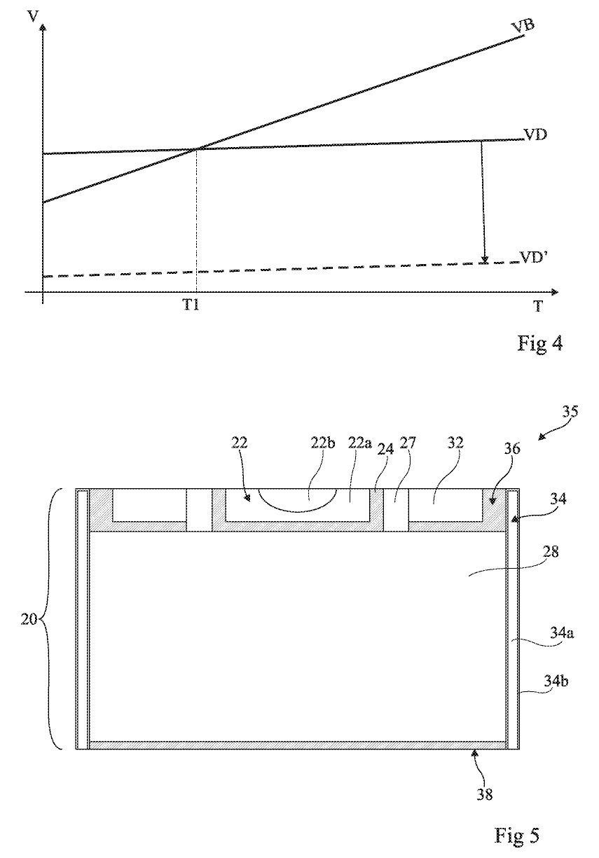

FIG. 4 illustrates the behavior of the SPAD of FIGS. 3A and 3B. More precisely, FIG. 4 illustrates the value of three voltages (V), the breakdown voltage VB of the SPAD 18 of FIGS. 3A and 3B, the depletion voltage VD of the SPAD 18 of FIGS. 3A and 3B when no voltage is applied to region 30 and the depletion voltage VD' of the SPAD 18 of FIGS. 3A and 3B when a voltage VPT is applied to region 30, as functions of the temperature (T).

Voltages VB and VD are identical to the voltages VB and VD represented in FIG. 2.

Voltage VPT is configured to decrease the depletion voltage. Voltage VPT is preferably configured not to have a significant impact on the breakdown voltage. When the SPAD is in operation, the voltage VPT is applied to region 30 and the value of the depletion voltage is decreased for all temperatures. For example, the depletion voltage is decreased by a same value for all temperatures. Therefore, the temperature at which the depletion voltage becomes higher than the breakdown voltage, in other words the temperature at which the curves corresponding to voltages VB and VD' cross each other, is decreased. For example, in FIG. 5, said temperature is below the x axis.

The voltage VPT is, for example, generated by a voltage generator circuit as a variable voltage. In other words, the voltage VPT applied depends, for example, on the temperature at which the device is operating.

FIG. 5 illustrates another embodiment of a SPAD 35. More precisely, FIG. 5 is a cut view of the SPAD 35 according to the same plan as FIG. 3A.

SPAD 35 comprises the same elements as SPAD 18 of FIGS. 3A and 3B. In other words, SPAD 35, like SPAD 18 of FIGS. 3A and 3B, is made in the substrate 20, is delimited by an element 34 and comprises: the cathode region 22, comprising parts 22a and 22b; the anode region 24; the region 28; the trench 27; and the region 32.

In the embodiment of FIG. 5, the element 34 is a conductive insulated wall. The element 34 therefore comprises a conductive or semiconductor core 34a and an insulating sheath, for example made of a dielectric material. For example, the element 34 is a back-side trench isolation.

The embodiment of FIG. 5 differs from the embodiment of FIGS. 3A and 3B in that the region 30 is replaced by regions 36 and 38. Regions 36 and 38 are preferably made of the same material, doped with the same conductivity type, and preferably with substantially the same concentration of dopants. Preferably, regions 36 and 38 are made of the same material as region 30 of FIGS. 3A and 3B. Regions 36 and 38 are made of a semiconductor material, for example made of silicon. Regions 36 and 38 are, for example, a doped region of the substrate 20. Regions 36 and 38 are preferably of the same conductivity type as the region 24. Regions 36 and 38 are, for example, p-doped regions.

Region 36 corresponds to the part 30b of region 30 of FIGS. 3A and 3B and to the portion of part 30a of region 30 covering the upper face of region 28. Region 38 corresponds to the portion of part 30b which covers the lower face of region 28.

In other words, the lower face of region 28, preferably the entirety of the lower face of region 28, is covered by, and for example in contact with, region 38, which constitutes a hole accumulation layer. The upper face of region 28 is covered by, and for example in contact with, regions 24 and 36 and by trench 24. Preferably, the entire upper face of region 28 is covered by, and, for example, in contact with, regions 24 and 36 and by trench 24. The lateral faces of region 28, preferably the entire lateral faces of region 28, are covered, and preferably in contact with, the element 34. Therefore, the lateral faces of region 28 are in inversion. In other words, holes accumulate at the interface between region 28 and element 34.

Region 38 is, for example, not biased. Region 36 is configured to receive the voltage VPT described in relation with FIGS. 3A, 3B and 4. The SPAD 35 operates preferably the same way as the SPAD 18 of FIGS. 3A and 3B.

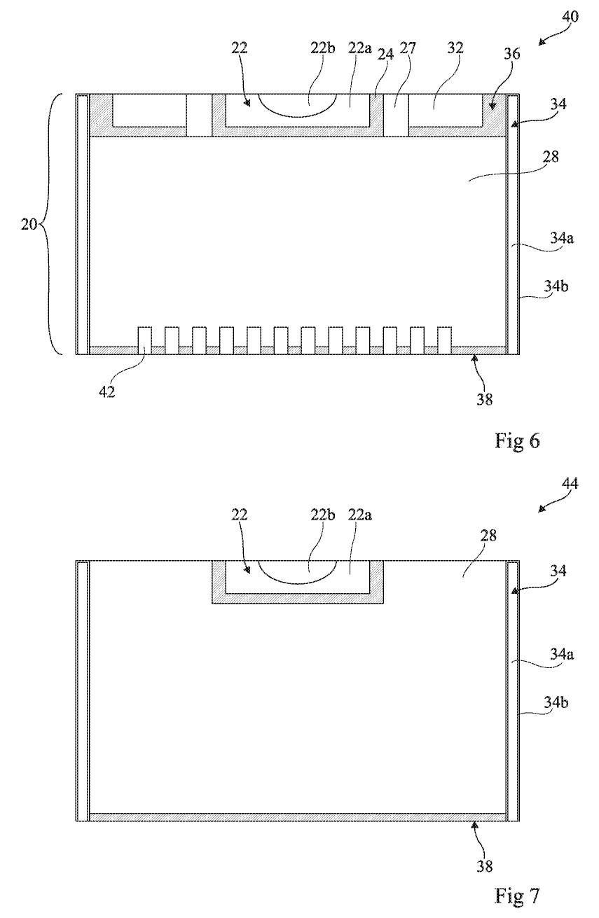

FIG. 6 illustrates another embodiment of a SPAD 40. More precisely, FIG. 6 is a cut view of the SPAD 40 according to the same plan as FIG. 3A.

SPAD 40 comprises the same elements as SPAD 35 of FIG. 5. In other words, SPAD 40, like SPAD 35 of FIG. 5, is made in the substrate 20, is delimited by an element 34, the element 34 comprising preferably the core 34a and the sheath 34b, and comprises: the cathode region 22, comprising parts 22a and 22b; the anode region 24; the trench 27; the region 32; the regions 36 and 38; and the region 28.

The SPAD 40 of FIG. 6 differs from the SPAD 35 of FIG. 5 in that the SPAD 40 comprises at least one trench 42, preferably at least 5 trench 42. Each trench 42 is, for example, made of an insulating material (for example SiO₂, TaO₅, or Al₂O₃) having a refractive index different from the refractive index of material 28. Each trench 42 extends in region 38 and in region 28. Each trench 42 extends from the lower face of the substrate, more precisely the lower face of region 38, to a level located in the region 28. Each trench 42 has a height lower than the sum of the height of the region 38 and the region 28. Therefore, no trench 42 is in contact with regions 22, 24, or 36. Preferably, region 38 is continuous. Therefore, trenches 42 do not separate region 38 into portions.

Alternatively, trenches can have a height lower than the height of region 38 and therefore be entirely in region 38.

Preferably, the trenches 42 do not extend outside the SPAD 40. Preferably, the trenches 42 do not extend outside the portion of the device delimited by the element 34.

FIG. 7 illustrates another embodiment of a SPAD 44. More precisely, FIG. 7 is a cut view of the SPAD 44 according to the same plan as FIG. 3A.

SPAD 44 comprises the same elements as SPAD 35 of FIG. 5. In other words, SPAD 44, like SPAD 35 of FIG. 5, is made in the substrate 20, is delimited by an element 34, the element 34 comprising preferably the core 34a and the sheath 34b, and comprises: the cathode region 22, comprising parts 22a and 22b; the anode region 24; the region 38; and the region 28.

The SPAD 44 differs from the SPAD 35 of FIG. 5 in that it does not comprises regions 36 and 32 and the trench 27. The region 24 is surrounded by the region 28. More precisely, the lateral and lower faces of region 24 are covered, and preferably in contact with, region 27. Region 27 has an upper surface coplanar with the upper face of the substrate 20 around the region 24.

The region 38 of FIG. 7 is configured to receive the voltage VPT. In other words, during the operation of the SPAD 44, the voltage VPT is applied to region 38.

An advantage of the described embodiments is that the SPAD can operates at lower temperatures without increasing the risk of afterpulsing.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A control method for a device comprising a single photon avalanche diode, wherein the single photon avalanche diode comprises: a substrate; a first semiconductor region in the substrate doped of a first conductivity type; a second semiconductor region doped of a second conductivity type opposite to the first conductivity type in the substrate, wherein the first and second semiconductor regions constitute a PN junction; and a third semiconductor region doped of the second conductivity type in the substrate and separated from the first and second semiconductor regions, the method comprising:
applying a first voltage to the third semiconductor region; and
operating the single photon avalanche diode with a value of the first voltage configured, during operation of the single photon avalanche diode, to decrease a value of a depletion voltage of the single photon avalanche diode.

2. The method according to claim 1, further comprising generating the first voltage as a variable voltage.

3. The method according to claim 1, further comprising generating the first voltage dependent on temperature.

4. The method according to claim 1, wherein the single photon avalanche diode is delimited by an element.

5. The method according to claim 4, wherein the element is a trench comprising a conductive core and a dielectric sheath.

6. The method according to claim 1, wherein the third semiconductor region laterally surrounds the first and second semiconductor regions.

7. The method according to claim 1, wherein the third semiconductor region is separated from the first and second semiconductor regions by a dielectric trench.

8. The method according to claim 1, wherein the single photon avalanche diode comprises a fourth semiconductor region separated from the first semiconductor region by the second semiconductor region.

9. The method according to claim 8, wherein the first and second semiconductor regions having surfaces coplanar with an upper face of the substrate, and wherein the fourth semiconductor region is surrounded by the second and third semiconductor regions and the dielectric trench.

10. The method according to claim 8, wherein the first and second semiconductor regions having surfaces coplanar with an upper face of the substrate, the upper face of the fourth semiconductor region is covered by the second and third semiconductor regions and the dielectric trench, the lateral faces of the fourth semiconductor region are covered by an element delimiting the single photon avalanche diode and the lower face of the fourth semiconductor region is covered by a fifth semiconductor region doped of the second conductivity type.

11. The method according to claim 8, wherein third semiconductor region is separated from the first and second semiconductor regions by the fourth semiconductor region.

12. The method according to claim 11, wherein the first and second semiconductor regions have surfaces coplanar with an upper face of the substrate, and wherein the third semiconductor region covers the lower face of the fourth semiconductor region.

13. A single photon avalanche diode device, comprising:
a substrate;
a first semiconductor region doped of a first conductivity type in the substrate;
a second semiconductor region doped of a second conductivity type opposite to the first conductivity type in the substrate, the first and second semiconductor regions constituting a PN junction;
a third semiconductor region doped of the second conductivity type in the substrate and separated from the first and second semiconductor regions;
a voltage generator configured to apply a first voltage to the third semiconductor region, wherein a value of the first voltage is configured so that a value of a depletion voltage of the single photon avalanche diode is decreased during operation of the single photon avalanche diode.

14. The single photon avalanche diode device according to claim 13, wherein the single photon avalanche diode is delimited by an element.

15. The single photon avalanche diode device according to claim 14, wherein the element is a trench comprising a conductive core and a dielectric sheath.

16. The single photon avalanche diode device according to claim 14, wherein the third semiconductor region laterally surrounds the first and second semiconductor regions.

17. The single photon avalanche diode device according to claim 14, wherein the third semiconductor region is separated from the first and second semiconductor regions by a dielectric trench.

18. The single photon avalanche diode device according to claim 17, wherein the single photon avalanche diode comprises a fourth semiconductor region separated from the first semiconductor region by the second semiconductor region.

19. The single photon avalanche diode device according to claim 18, wherein the first and second semiconductor regions having surfaces coplanar with an upper face of the substrate, and wherein the fourth semiconductor region is surrounded by the second and third semiconductor regions and the dielectric trench.

20. The single photon avalanche diode device according to claim 18, wherein the first and second semiconductor regions having surfaces coplanar with an upper face of the substrate, the upper face of the fourth semiconductor region is covered by the second and third semiconductor regions and the dielectric trench, the lateral faces of the fourth semiconductor region are covered by an element delimiting the single photon avalanche diode and the lower face of the fourth semiconductor region is covered by a fifth semiconductor region doped of the second conductivity type.

21. The single photon avalanche diode device according to claim 18, wherein third semiconductor region is separated from the first and second semiconductor regions by the fourth semiconductor region.

22. The single photon avalanche diode device according to claim 21, wherein the first and second semiconductor regions have surfaces coplanar with an upper face of the substrate, and wherein the third semiconductor region covers the lower face of the fourth semiconductor region.

23. The single photon avalanche diode device according to claim 13, wherein the first voltage is generated by the voltage generator as a variable voltage.

24. The single photon avalanche diode device according to claim 13, wherein the first voltage is generated by the voltage generator dependent on temperature.
